(19) United States
(12) Patent Application Publication
(10) Pub. No.: US 2017/0129273 A1
(43) Pub. Date: May 11, 2017

(54) SECURITY DEVICES FOR SECURITY SUBSTRATES

(71) Applicant: DE LA RUE INTERNATIONAL LIMITED, HAMPSHIRE (GB)

(72) Inventor: Lawrence George COMMANDER, Berkshire (GB)

(73) Assignee: DE LA RUE INTERNATIONAL LIMITED, HAMPSHIRE, UNITED KINGDOM;

(21) Appl. No.: 15/411,094

(22) Filed: Jan. 20, 2017

Related U.S. Application Data
(62) Division of application No. 11/990,563, filed on Feb. 15, 2008.

(30) Foreign Application Priority Data
Aug. 15, 2005 (GB) GB0516724.2

(51) Int. Cl. B42D 25/445; B42D 25/373; B42D 25/21; B42D 25/351; B42D 25/364; D21H 21/42; C23C 14/24; C23C 14/20; C23C 14/58; C25D 5/56; C25D 5/48; B42D 25/355; B42D 25/328

(52) U.S. Cl. CPC B42D 25/445; B42D 25/355; B42D 25/373; B42D 25/21; B42D 25/351; B42D 25/364; B42D 25/328; C23C 14/24; C23C 14/20; C23C 14/5873; C25D 5/56; C25D 5/48; D21H 21/42

(57) ABSTRACT

A security device for security substrates, such as paper used for making security documents, such as banknotes, having anti-counterfeitable features and methods of making are provided. The security device has a carrier of at least partially light transmitting polymeric material. A carrier bears a plurality of first indicia which are easily visible to the human eye. The first indicia are defined by a plurality of smaller second indicia which are less visible to the human eye positioned relative to each other to enable the first indicia to be visualized.

### CROSS REFERENCE TO RELATED APPLICATIONS

This application is a divisional of U.S. application Ser. No. 11/990,563 filed on Feb. 15, 2008, which is a national stage application of International Application No. PCT/GB2006/002711 filed on Jul. 20, 2006, which claims the benefit of British Application No. GB0516724.2 filed on Aug. 15, 2005, the contents of all of which are incorporated by reference herein.

### BACKGROUND

### 1. Field of the Invention

The invention relates to a security device for security substrates, such as paper, used for making security documents, such as bank notes, having anti-counterfeitable features.

### 2. Description of Related Art

It is generally known to include elongate elements in paper or other substrates, usually as a security feature. Such elements can be threads, strips or ribbons of, for example, plastics film, metal foil, metallized plastic, metal wire. These elongate elements are included in the thickness of the substrate to render imitation of documents produced therefrom more difficult. These elements help in the verification of the documents as they render the view of the documents in reflected light different from that in transmitted light. To increase the security provided by the inclusion of such an elongate element, it is also known to endow the element itself with one or more verifiable properties over and above its presence or absence. Such additional properties include magnetic properties, electrical conductivities, the ability to absorb x-rays, fluorescence, optically variable effects and thermochromic behavior.

As a further security feature, it has been found to be particularly advantageous to provide windows in one side of the surface of the substrate, which expose such elongate elements at spaced locations. Examples of methods of manufacturing paper incorporating security elements with or without windows are described below. It should be noted that references to “windowed thread paper” include windowed paper incorporating any elongate security element.

EP-A-0059056 describes a method of manufacture of windowed thread paper on a cylinder mold paper-making machine. The technique involves embossing the cylinder mold cover to form raised regions and bringing an impermeable elongate security element into contact with the raised regions of the mold cover, prior to the contact entry point into a vat of aqueous paper stock. Where the impermeable security element makes intimate contact with the raised regions of the embossing, no fiber deposition can occur and windows are formed in the surface of the paper. After the paper is fully formed and couched from the cylinder mold cover, water is extracted from the wet fiber mat and the paper is passed through a drying process. In the finished paper the regions of the security element which are exposed in the windows are visible in reflected light on one side of the paper, which is commonly used for mainly banknotes.

As an alternative to elongate elements, patches and foils can be applied to a surface of a substrate to cover a window or aperture.

The widespread use of security documents having security elements exposed on windows along the length of the element has resulted in enhanced security. A security document of this type provides this enhancement as, when viewed in transmitted light, the security element provides a different view from that which is seen under reflected light, where parts of the security element are readily visible in the window. However, there is a continual need for further enhanced security features to render the task of a would be counterfeiter more difficult.

U.S. Pat. No. 5,573,639 describes a safeguarding thread in which metallic stripes are provided on a transparent or translucent plastic substrate. Visually and/or machine readable information extends over several of the stripes and is made up of metal free or partly metal free characters having a contrasting appearance to the metal stripes.

EP-A-0659587 also describes a security element which has a first information portion which is visually recognizable without aids and a second information portion which is harder to resolve visually due to its smaller size as compared to the first information portion. Effectively the design contains two sets of demetallized indicia, one significantly smaller than the other. A security element of this type therefore provides two levels of authentication and the fact that the two designs are visually similar increases the security.

### SUMMARY

It is an object of the present invention to further enhance the security of security devices such as elongate security elements, foils and particles.

According to the invention there is provided a security device for a security substrate said device comprising a carrier of an at least partially light transmitting polymeric material, said carrier bearing a plurality of first indicia which are easily visible to the human eye, said first indicia being defined by a plurality of smaller second indicia which are less visible to the human eye positioned relative to each other to enable the first indicia to be visualized.

The invention provides an improvement in the anti-counterfeitability of the security devices over the construction described in EP-A-659587 in that it introduces complex requirements of positioning and registration of the smaller indicia to enable the larger indicia to be visualized. In addition, as the smaller indicia are used to create the larger indicia, the overall design takes up less space on the security element than on the prior art threads, where the smaller and larger construction portions are in separate locations. This is particularly important for windowed security devices where design space is limited to the window region.

The present invention also allows the controlled use of a limited set of characters, such as a bank's initials or note dominations, which can be laid out on a security device such that even when the vertical position is not registered, there is the ability to have a full set of characters falling within a window space on each banknote. This improves the readability of the security feature as it is given a uniform background. Such a set of characters can then combine both macro- and micro-elements in the limited space compared to the prior art devices.

An additional advantage is that the invention presents a visual image which is more interesting than those of the prior art. Making the security element interesting to the viewer increases the probability that a member of the public will view and inspect the device, and the security document as a whole, which means that the security device has a greater security impact. This has a benefit over visually complex devices, such as those described in U.S. Pat. No. 5,573,639, which very easily become confusing, particularly when the document in which the security device is incorporated is overprinted. Due to the manner in which the images are built up in the present invention, this is not a problem and the large characters remain easily visible.

With the improvements in modern scanners and desk-top printing equipment, it is also necessary for manufacturers to increase the complexity of designs used on security documents, but this must be done without compromising the public accessibility or the readability of the security features. The present invention provides a simple to recognize public security feature, with a more complex feature, which is much harder to copy with modern scanning equipment

### BRIEF DESCRIPTION OF THE DRAWINGS

The invention will now be described, by way of example only, with reference to, and as shown in the accompanying drawings in which:

FIG. 1 is a plan view of an elongate security element according to the present invention having metallized indicia;

FIG. 2 is a plan view of an alternative embodiments of the present invention, in which the security device is provided with a different form of indicia;

FIG. 3 is a plan view of another alternative embodiments of the present invention, in which the security device is provided with a different form of indicia;

FIG. 4 is a plan view of a security article incorporating the security device of FIG. 3;

FIGS. 5 to 11 are plan views of alternative embodiments of the present invention, in which the security device is provided with different forms of indicia; and

FIG. 12 is yet another alternative embodiment of the security device according to the invention wherein the indicia are of different sizes.

### DETAILED DESCRIPTION

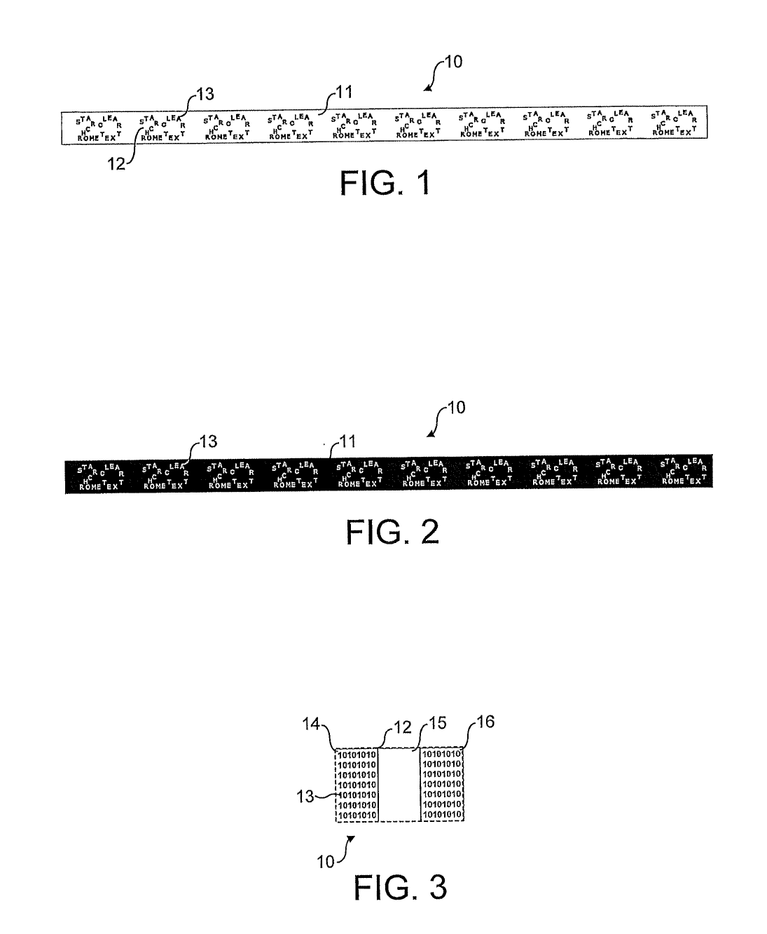

FIG. 1 shows a security device in the form of an elongate security element 10 according to a first embodiment of the present invention for partially embedding into a fibrous substrate, such as security paper. The security element 10 comprises a carrier 11 of a suitable plastic material which is flexible and water impermeable, and which is at least translucent and partially light transmissive, but preferably substantially transparent. A suitable material would be PET. The security element 10 is provided with large easily legible indicia 12 which are formed from smaller indicia 13.

In the example shown in FIG. 1, the large indicia 12 comprise the numerals “2” and “0” forming the number “20”, wherein the “2” and “0” are constructed from the small, less easily legible metallized letters 13 which read in sequence “STARCHROME” and “CLEARTEXT”. The small indicia 13 are of a size which is more difficult to discern visually by the unaided eye, but which provides an additional degree of anti-counterfeitability as they are significantly more difficult for the counterfeiter to produce. However, once the eye has focused on the large text, it becomes easier to realize the presence of the small indicia 13 and to recognize them. The smaller indicia 13 may be provided by printed, conductive or non-conductive, metallic or other opaque inks or by other known metallization or demetallization processes.

Preferably, the width of the security element 10 is in the range of 1 to 30 mm whilst the height of the larger indicia 12 is in the range of 0.8 to 28.0 mm, and more preferably 0.8 to 8.0 mm. The height of the smaller indicia 13 is preferably in the range of 0.2 to 6 mm and more preferably 0.2 to 2.00 mm.

In a preferred embodiment, for a security element of 8 mm width, the height of the large indicia 12 is preferably 6 mm, with the height of the smaller indicia 13 being 1 mm. For a security element of 4 mm width, the height of the large indicia 12 is 2 mm and the height of the smaller indicia 13 is 0.4 mm. The smaller indicia 13 can be of a size where they can only be resolved by a viewing aid such as a magnifying glass.

As shown in FIG. 2, the smaller indicia 13 may alternatively comprise demetallized indicia. In this example the carrier 11 is metallized to provide a metal layer of aluminum or another suitable metal. This can be done by vacuum deposition, electroplating or another suitable method. The metallized carrier 11 is then partially demetallized using a known method, such as the resist and etch method, to provide clear regions which form the indicia 13. The indicia may be formed from regions of reduced metal thickness, as described in WO 2004/014665.

In both of the embodiments shown in FIGS. 1 and 2, the metallic regions may be provided by printing the security element 10 with a metal effect ink having a metallic appearance such as Metalstar® inks sold by Eckart. Such metal effect inks do not, however, necessarily provide conductivity. It is advantageous, however, that the indicia 12/13, where these comprise metallic material, and/or the security element 10 as a whole, provide conductive properties that enable the thread to be machine detectable for authentication or denomination sorting purposes.

In the current invention only the small indicia are physically produced during the metallization, demetallization or printing process. The larger indicia are created by the positioning and registration of the smaller indicia. Generating a conventional metallic security thread with large and small demetallized characters cab be problematic because of the large difference in stem width between the large and small characters. It is difficult to optimize the etchant process to efficiently achieve both fine and coarse demetallized regions. For example, if the process is optimized for the fine regions then the coarse regions will not be completely demetallized, and if the machine is optimized for the coarse regions, then the resolution of the fine regions is reduced due to too much metal being removed. An advantage of the current invention is that as the smaller indicia are used to define the larger indicia the demetallization process can be optimized for the stem width of the smaller characters and therefore the optimum resolution can be achieved. The demetallization process can be further optimized by generating the small characters with a constant stem width.

As a further alternative the indicia can be provided by printing the security element 10 with an optically variable ink, such as OVI® as supplied by Sicpa, or other colored opaque or transparent inks. One or more colors may be used to create multicolored designs, such as national flags. In the embodiment shown in FIG. 3, the first indicia 12 comprise the French flag. A first section 14 is printed with the second indicia 13, namely small numerals representing the denomination of a banknote (e.g., £10) which are printed in red ink. A second section 15 is left clear, so that the white color of the underlying paper shows it through and a third section 16 is printed with similar numerals to those in section 14, but in blue ink. The outline is shown for the sake of clarity and is not part of the design.

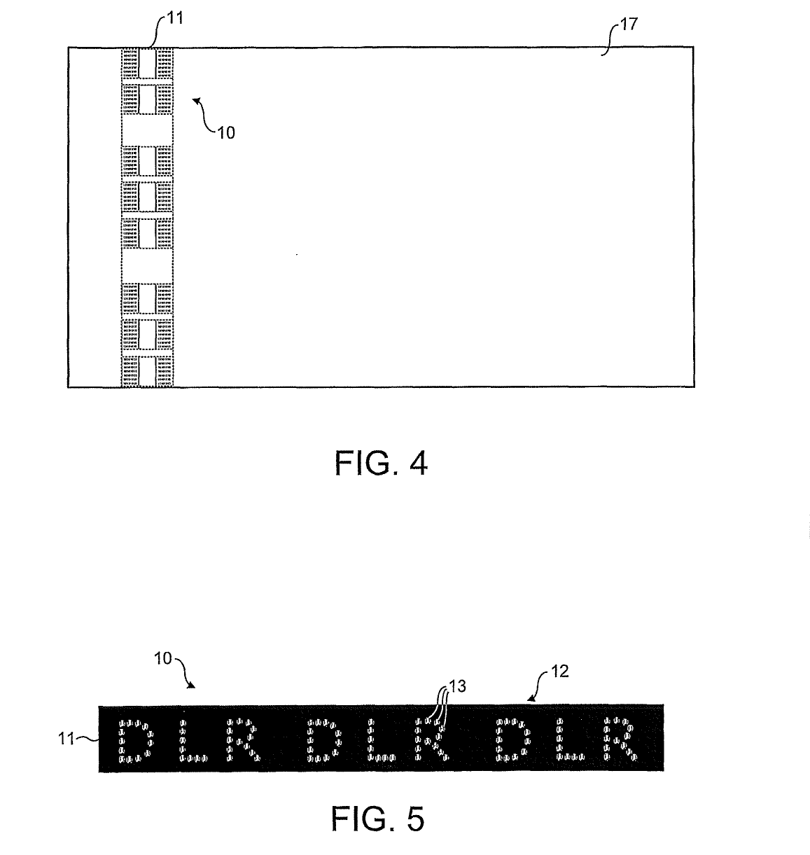

In FIG. 4 the security device 10 of FIG. 3 is shown as an elongate security element which is partially embedded in a security substrate from which a banknote or other security article 17 is formed. The security element is partially exposed at windows at the surface of the substrate.

Obviously any of the above mentioned inks can be combined either with other inks or with vacuum deposited metal layers.

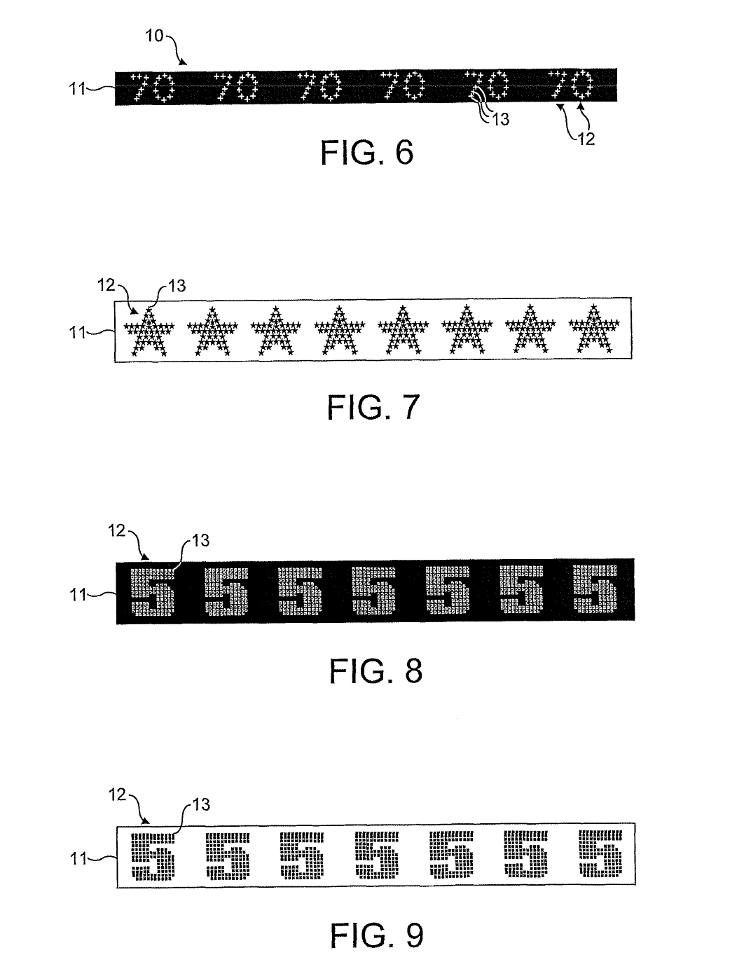

As shown in FIGS. 5 and 6, symbols or pictorial elements may be used as the smaller indicia 13 instead of alphanumeric characters, which make up the alphanumeric large indicia 12 in those figures “DLR” and “70” respectively.

FIG. 7 shows a further example whereby the smaller indicia 13 comprise positive opaque symbols, such as stars, this time making up the larger indicia 12, which is also a symbol of a larger star 12. The carrier 11 is clear so the indicia 12/13 will be seen as a positive design on a clear background. FIGS. 8 and 9 are further embodiments whereby the large indicia 12 are numerals “5”, made up of smaller indicia 13 which are also the numerals “5”. In FIG. 8, the large indicia 12 would appear as negative metallized characters, made up of smaller indicia 13 which are negative demetallized characters formed on a metallized carrier 11. In FIG. 9, similar to FIG. 7, the large indicia 12 would appear positive, being made up of smaller indicia 13 which are positive metallized characters on a clear carrier 11.

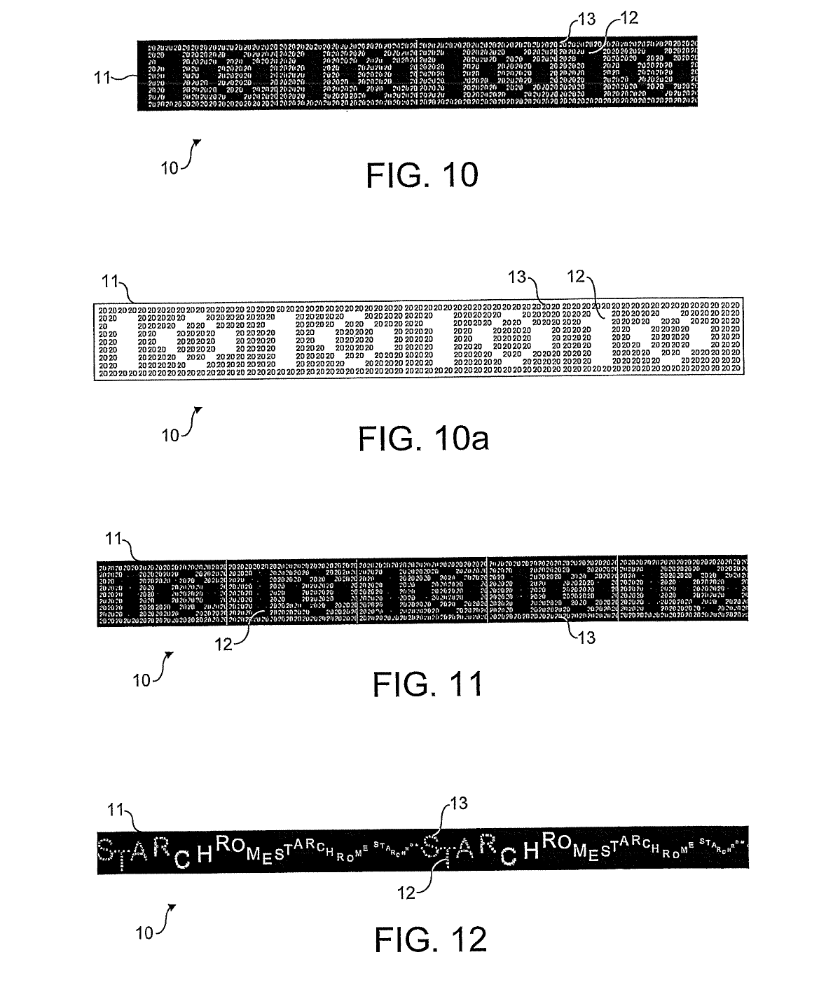

FIG. 10 shows a further alternative embodiment of a security device according to the invention. In this embodiment the carrier 11 is metallized and then partially demetallized to form repeating smaller indicia 13 (the numerals “20”) which closely repeat along the length and across the width of the security element 10. The larger indicia 12 are provided by solid metal regions (forming the numerals “10”) outlined by a plurality of the smaller indicia 13.

In FIG. 10 the large indicia 12 would appear positive, being made up of smaller negative indicia 13. FIG. 10a shows a further alternative embodiment in which the smaller indicia 13 are metallized characters on a clear carrier 11. The larger indicia 12 are provided by regions of the clear carrier 11 outlined by a plurality of the smaller metallized indicia 13. In FIG. 10a the large indicia 12 would appear negative, being made up of smaller positive indicia 13.

FIG. 11 shows an embodiment of a security device similar to that shown in FIG. 10, which has been modified such that smaller indicia 13 are provided along and across the entire security element 10. However, the large indicia 12 are created by modifying the appearance of the smaller indicia 13 to provide a visible contrast. For example the font or stem width of indicia 13 may be changed. Alternatively the density of the metal used in forming the smaller indicia 13 may be changed to provide the contrast for example by chemical etching to remove some but not all of the metal present in the regions of the said indicia 13. In a further embodiment, the color of the smaller indicia may be changed to provide the contrast.

In a further alternative embodiment of the invention in which the sizes of both the smaller indicia 13 and the large indicia 12 on the security device vary along the length of a security element 10. In the embodiment illustrated in FIG. 12 the size of the indicia 12,13 reduces over a first length of the element 10 from a starting size to a finishing size until a point is reached whereby the larger indicia 13 are replaced by single line indicia of a size a little smaller than the finishing size of the larger indicia 12. The single line indicia continue reducing in size over a second length of the element 10 until they nearly reach the starting size of the smaller indicia 13. At this point a further first length of larger and smaller indicia 12,13 commences. The first and second lengths appear to merge into each other. In further examples in the invention, either the size of the large indicia 12 may vary or the size of the smaller indicia 13, but not both.

A further variation on the embodiments described previously is to provide the device 10 with an optical effect layer. Examples of suitable optical effect layers include liquid crystal polymers, liquid crystal pigmented ink layers, iridescent print layers, dielectric thin film structures.

The optical effect layer may be used in addition to or instead of a demetallized layer. For example, an iridescent or liquid crystal pigmented ink layer can be printed to define the large and small indicia 12/13. More preferably the large and small indicia 12/13 are defined by printing a darkly colored ink layer that can contain other functional pigments such as carbon black or magnetics, which is then overprinted all-over with the iridescent or liquid crystal ink layer.

Where a polymer liquid crystal film layer, holographic layer or thin film dielectric structure is applied this is preferably, but not necessarily, done in conjunction with a metal layer. For example, where the security device 10 is to be provided with a holographic layer, the demetallized layer can be used as a reflection-enhancing layer. A polymer carrier 11 is first coated with an embossing lacquer which is then embossed with a holographic relief. The embossed layer is then metallized and the resulting metal layer partially demetallized. The resulting structure can be provided with an optional protective layer

In an alternative holographic embodiment, a polymer film 11 is coated with an embossing lacquer and then embossed with a holographic relief structure. A transparent high refractive index layer (e.g., ZnS) is coated over the holographic relief layer. The large and small indicia are then provided by printing opaque or transparent inks. The ink may be a metal effect ink.

In a further alternative embodiment, a holographic transfer construction may be used. This is essentially the same as described above, but with the addition of a wax release layer and an adhesive layer. The wax release layer is provided between the polymer carrier 11 and the metal or lacquer layer such that after transfer the polymer can be removed. A hot melt or pressure sensitive adhesive layer is provided on the opposite surface to the carrier 11, i.e., the surface that comes into contact with the substrate.

In a further variation thermochromic and liquid crystal materials can be used, such as those described in EP-A-608078 and WO-A-03061980.

It is also widely known, in the field of manufacturing security devices 10, to provide additional machine readable features. Machine readable properties typical to this class of security device 10 are conductivity, magnetism, and luminescence. Numerous methods have been described within the prior art for producing security devices with machine readable characteristics. Examples of such devices can be found in EP-A-319517, EP-A-516790, EP-A-998396, EP-A-961996 and EP-A-1334844.

Where the security devices are security elements, they may be inserted into a paper, or other, substrate so that they are either wholly or partially embedded within the substrate. Whilst security elements can be used in wholly embedded or windowed form, the latter is preferred as the indicia are then easily recognizable in both reflected and transmitted light, rather than in just transmitted light as in the wholly embedded form. The security elements 10 of the present invention may also be used in the construction such as those described in EP-A-1141480 whereby the element is exposed in windows on one surface of the substrate and the element is wholly exposed along its length on the other side.

In other embodiments, instead of elongate security elements, patches, foils and the like may be applied to a surface of the substrate. These may be applied such that they cover windows or apertures formed during the manufacture of the substrate or in a subsequent cutting process, such as laser or die cutting, so that part of the device is revealed on one side of the substrate in those windows or apertures.

The indicia or repeating pattern may be registered with the windows in the machine direction, so that an identical portion of the indicia or pattern is seen in each window. This requires the use of a registration process, such as that described co-pending application GB 0409736.6.

The finished security paper may be printed on one or both sides to identify the article or document formed from the paper. This printing may include indicia which matches the indicia 12 or 13.

The security substrate is used to manufacture security articles such as banknotes, vouchers, bonds, passports, security labels, certificates and the like.

What is claimed is:

1. A method of producing a security device, comprising the steps of:
providing a carrier of an at least partially light transmitting polymeric material;
providing, via a metallizing process, a metal layer on the carrier; and
removing, via a de-metallizing process, the metal layer in a plurality of demetallized regions and in a pattern, each demetallized region of the plurality of demetallized regions defining a small negative character having a first stem width, the pattern of the plurality of demetallized regions defining a large character, wherein the removing step comprises optimizing the demetallizing process to the first stem width.

2. The method of claim 1, wherein the step of optimizing the demetallizing process comprising optimizing so that the first stem width is a constant stem width.

3. The method of claim 1, wherein the step of optimizing the demetallizing process comprising optimizing so that the small negative characters have a height in a range of 0.2 mm to 2.0 mm.

4. The method of claim 3, further comprising selecting the pattern so that the large character has a height in a range of 0.8 mm to 28.0 mm.

5. The method of claim 4, wherein the step of selecting the pattern comprises selecting the pattern so that the large negative character is selected from the group consisting of alphabetic characters, numeric characters, symbols, pictorial elements, and any combination thereof.

6. The method of claim 5, wherein the small negative characters are selected from the group consisting of alphabetic characters, numeric characters, symbols, pictorial elements, and any combination thereof.

7. The method of claim 1, wherein the small negative characters are selected from the group consisting of alphabetic characters, numeric characters, symbols, pictorial elements, and any combination thereof.

8. A method of producing a security substrate, comprising the steps of:
providing a carrier of an at least partially light transmitting polymeric material;
providing, via a metallizing process, a metal layer on the carrier;
removing, via a de-metallizing process, the metal layer in a plurality of demetallized regions and in a pattern to provide a security device, each demetallized region of the plurality of demetallized regions defining a small negative character having a first stem width, the pattern of the plurality of demetallized regions defining a large character, wherein the removing step comprises optimizing the demetallizing process to the first stem width; and
at least partially embedding the security device into a substrate having a plurality of windows so that an identical portion of the pattern is seen in each window to define the security substrate.

9. The method of claim 8, wherein the step of optimizing the demetallizing process comprising optimizing so that the first stem width is a constant stem width.

10. The method of claim 8, wherein the step of optimizing the demetallizing process comprising optimizing so that the small negative characters have a height in a range of 0.2 mm to 2.0 mm.

11. The method of claim 10, further comprising selecting the pattern so that the large character has a height in a range of 0.8 mm to 28.0 mm.

12. The method of claim 11, wherein the step of selecting the pattern comprises selecting the pattern so that the large negative character is selected from the group consisting of alphabetic characters, numeric characters, symbols, pictorial elements, and any combination thereof.

13. The method of claim 8, wherein the small negative characters are selected from the group consisting of alphabetic characters, numeric characters, symbols, pictorial elements, and any combination thereof.

14. The method of claim 8, wherein the embedding step comprises embedding the security device into the substrate so that the plurality of windows are on one surface of the substrate and the security device is wholly exposed on an opposite surface of the substrate.

15. The method of claim 8, wherein the security substrate is a security document.

16. The method of claim 15, wherein the security document is an article selected from the group consisting of a banknote, a voucher, a bond, a passport, a security label, and a certificate.

17. The method of claim 8, wherein the embedding step comprises fully embedding the security device into the substrate.
